(19) United States
(12) Patent Application Publication
(10) Pub. No.: US 2025/0340428 A1
(43) Pub. Date: Nov. 6, 2025

(54) SYSTEMS AND METHODS FOR INTEGRATED FUELING AND CHARGING OF VOCATIONAL VEHICLES

(71) Applicant: Oshkosh Corporation, Oshkosh, WI (US)

(72) Inventor: Vince Schad, Oshkosh, WI (US)

(73) Assignee: Oshkosh Corporation, Oshkosh, WI (US)

(21) Appl. No.: 19/197,511

(22) Filed: May 2, 2025

Related U.S. Application Data
(60) Provisional application No. 63/642,052, filed on May 3, 2024.

(51) Int. Cl. B67D 7/32; B60K 6/28; B60K 15/03; B60L 53/14; B60S 5/02; B65F 3/02; G01M 3/04; G01R 31/69

(52) U.S. Cl. CPC B67D 7/3209; B60K 6/28; B60K 15/03006; B60L 53/14; B60S 5/02; B65F 3/02; G01M 3/04; G01R 31/69; B60Y 2200/144; B60Y 2200/92; B60Y 2400/10; B60Y 2400/112; B60Y 2400/30; B65F 2003/0283

(57) ABSTRACT

A method for operating an integrated fueling and charging system includes electrically coupling an electrical output of the integrated fueling and charging system with an electrical input of a vehicle, fluidly coupling a gas output of the integrated fueling and charging system with a gas input of the vehicle, performing a first connection test on a first connection between the electrical output and the electrical input, performing a second connection test on a second connection between the gas output and the gas input, and responsive to the first connection passing the first connection test and the second connection passing the second connection test, simultaneously providing electricity and fuel gas from the integrated fueling and charging system to the vehicle.

### CROSS-REFERENCE TO RELATED PATENT APPLICATION

This application claims the benefit of and priority to U.S. Provisional Application No. 63/642,052, filed May 3, 2024, the entire contents of which are hereby incorporated by reference herein.

### BACKGROUND

Refuse vehicles collect a wide variety of waste, trash, and other material from residences and businesses. Operators of the refuse vehicles transport the material from various waste receptacles within a municipality to a storage or processing facility (e.g., a landfill, an incineration facility, a recycling facility, etc.).

### SUMMARY

One embodiment relates to a method for operating an integrated fueling and charging system. The method includes electrically coupling an electrical output of the integrated fueling and charging system with an electrical input of a vehicle, fluidly coupling a gas output of the integrated fueling and charging system with a gas input of the vehicle, performing a first connection test on a first connection between the electrical output and the electrical input, performing a second connection test on a second connection between the gas output and the gas input, and responsive to the first connection passing the first connection test and the second connection passing the second connection test, simultaneously providing electricity and fuel gas from the integrated fueling and charging system to the vehicle.

Another embodiment relates to an integrated fueling and charging system. The integrated fueling and charging system includes a charging system configured to supply electricity to a vocational vehicle, a fueling system configured to supply fuel gas to the vocational vehicle, and one or more processing circuits. The charging system includes an electrical output configured to electrically couple with an electrical input of the vocational vehicle. The fueling system includes a gas output configured to fluidly couple with a gas input of the vocational vehicle. The one or more processing circuits are configured to perform a first connection test on a first connection between the electrical output and the electrical input, perform a second connection test on a second connection between the gas output and the gas input, and responsive to the first connection passing the first connection test and the second connection passing the second connection test, operate the charging system and the fueling system to simultaneously provide the electricity and the fuel gas to the vocational vehicle.

Another embodiment relates to a system. The system includes a vehicle, a fueling system, a charging system, and one or more processing circuits. The vehicle includes a fuel gas tank configured to store a fuel gas, a gas input fluidly coupled to the fuel gas tank, a battery configured to store electricity, and an electrical input electrically coupled to the battery. The fueling system includes a gas output configured to fluidly couple with the gas input. The charging system includes an electrical output configured to electrically couple with the electrical input. The one or more processing circuits are configured to perform a first connection test on a first connection between the electrical output and the electrical input, perform a second connection test on a second connection between the gas output and the gas input, and responsive to the first connection passing the first connection test and the second connection passing the second connection test, operate the charging system and the fueling system to simultaneously provide the electricity and the fuel gas to the vehicle.

This summary is illustrative only and is not intended to be in any way limiting. Other aspects, inventive features, and advantages of the devices or processes described herein will become apparent in the detailed description set forth herein, taken in conjunction with the accompanying figures, wherein like reference numerals refer to like elements.

### BRIEF DESCRIPTION OF THE DRAWINGS

The disclosure will become more fully understood from the following detailed description, taken in conjunction with the accompanying figures, wherein like reference numerals refer to like elements, in which:

FIG. 1 is a perspective view of a refuse vehicle, according to an exemplary embodiment;

FIG. 2 is a block diagram of an electric power take-off system of the refuse vehicle of FIG. 1 according to an exemplary embodiment;

FIG. 3 is a block diagram of onboard storage devices of the refuse vehicle of FIG. 1, according to an exemplary embodiment;

FIG. 4 is a block diagram of the refuse vehicle of FIG. 1 and an integrated fueling and charging system, according to an exemplary embodiment; and

FIG. 5 is a flow chart of a process for operating an integrated fueling and charging system, according to an exemplary embodiment.

Before turning to the figures, which illustrate the exemplary embodiments in detail, it should be understood that the present application is not limited to the details or methodology set forth in the description or illustrated in the figures. It should also be understood that the terminology is for the purpose of description only and should not be regarded as limiting.

### DETAILED DESCRIPTION

Before turning to the figures, which illustrate the exemplary embodiments in detail, it should be understood that the present application is not limited to the details or methodology set forth in the description or illustrated in the figures. It should also be understood that the terminology is for the purpose of description only and should not be regarded as limiting.

### Overview

Referring generally to the Figures, various embodiments of a refuse vehicle are shown that include a plurality of onboard storage devices that are configured to store fuel gas and/or electricity that may be used to operate systems of the refuse vehicle. For example, the refuse vehicle may be configured as a natural gas powered refuse vehicle that includes a gas storage tank configured to store natural gas that may be used to generate energy to operate the systems of the refuse vehicle. The refuse vehicle may also include a battery configured to store electricity that may also be used to operate the systems of the refuse vehicle. The refuse vehicle may include an integrated fueling and charging system that is configured to provide the fuel and electricity to the refuse vehicle to be stored in the onboard storage devices.

For example, in the context of a natural gas powered refuse vehicle, the integrated fueling and charging system may be configured provide natural gas and electricity to the natural gas powered refuse vehicle. The integrated fueling and charging system may be configured to simultaneously provide the fuel and the electricity to the refuse vehicle to reduce an amount of time that the refuse vehicle spends being fueled by the integrated fueling and charging system (as compared to providing fuel and gas as separate inputs). The integrated fueling and charging system may be configured to provide the natural gas and the electricity to the natural gas powered refuse vehicle simultaneously.

The integrated fueling and charging system is also configured to reduce the risk of electrical and combustion hazards associated with simultaneous fueling and charging operations. Such issues may arise if connections between the refuse vehicle and the fueling and charging systems are inadequate (e.g., improper, bad, etc.). In such instances, the fuel and/or the electricity may bypass the connections, leaking or causing electrical arcing into a surrounding environment. For example, in the case of a faulty or inadequate electrical connection, the electricity from the integrated fueling and charging system to the vehicle may arc away from the electrical connections, which may generate sparks around the electrical connection. Additionally, if a natural gas connection is inadequate, the natural gas flowing from the fueling system to the vehicle may leak outside of the natural gas connection. If the sparks from the electricity interact with the natural gas, the natural gas could ignite (e.g., explode, etc.), causing damage to the fueling or charging system and/or the vehicle itself.

The integrated fueling and charging system of the present disclosure is configured to mitigate the risk of electrical and/or combustion hazards by performing an electrical connection test on the electrical connection between the integrated fueling and charging system and the refuse vehicle, and/or a gas connection test on the gas connection between the integrated fueling and charging system and the refuse vehicle prior to simultaneously supplying the fuel and the electricity to the refuse vehicle. If the electrical connection passes the electrical connection test and the gas connection passes the gas connection test, the integrated fueling and charging system may simultaneously provide the fuel and the electricity to the refuse vehicle. However, if at least one of the electrical connection fails the electrical connection test or the gas connection fails the gas connection test, the integrated fueling and charging system may limit fueling and charging of the refuse vehicle. In some embodiments, if the electrical connection fails the electrical connection test or the gas connection fails the gas connection test, the integrated fueling and charging system may provide the electricity to the refuse vehicle and the gas to the refuse vehicle at separate times. As a result, the integrated fueling and charging system may increase operator safety and reduce the risk of damage to the vehicle during fueling and charging operations (e.g., by providing the fuel and the electricity to the refuse vehicle simultaneously only when it is safe to do so, and by providing the fuel and the electricity to the refuse vehicle during separate times when it is not safe to simultaneously fuel and charge the vehicle).

### Refuse Vehicle

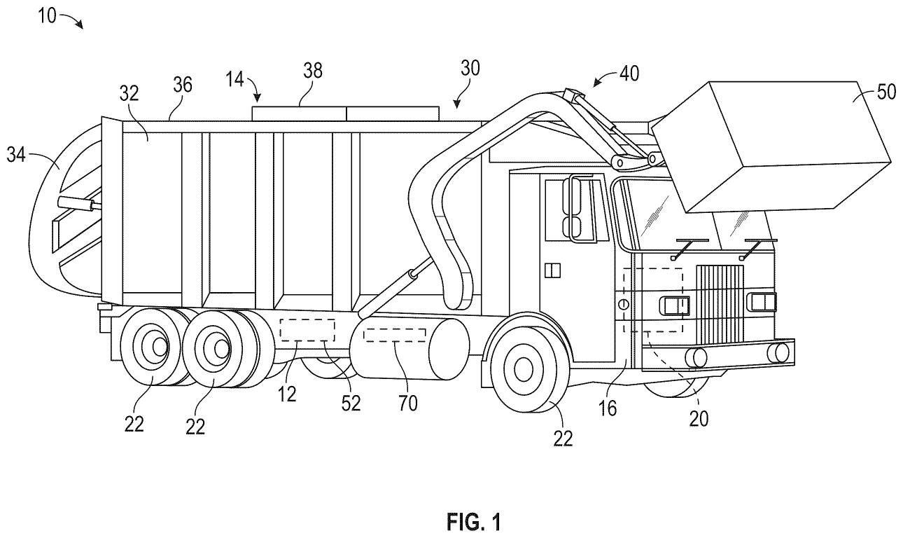

Referring to FIG. 1, a vehicle, shown as refuse vehicle 10 (e.g., garbage truck, waste collection truck, sanitation truck, etc.), includes a chassis, shown as a frame 12; a body assembly, shown as body 14, coupled to the frame 12 (e.g., at a rear end thereof, etc.); and a cab 16, coupled to the frame 12 (e.g., at a front end thereof, etc.), according to some embodiments. In other embodiments, the vehicle is configured as a vocational vehicle other than the refuse vehicle 10. For example, the vehicle may be configured as a delivery truck, a dump truck, a tow truck, a fire truck, a concrete mixer, or any other type of vocational vehicle. The cab 16 may include various components to facilitate operation of refuse vehicle 10 by an operator (e.g., a seat, a steering wheel, hydraulic controls, a user interface, switches, buttons, dials, etc.). The cab 16 may also include components that can execute commands automatically to control different subsystems within the vehicle (e.g., computers, controllers, processors, etc.). The refuse vehicle 10 further includes a prime mover 20 coupled to the frame 12 at a position beneath the cab 16. The prime mover 20 provides power to a plurality of motive members, shown as wheels 22, and to other systems of the vehicle (e.g., a pneumatic system, a hydraulic system, an electric system, etc.). A pair of wheels 22 may be coupled to an axle. The refuse vehicle 10 may include at least two axles. In some embodiments, the refuse vehicle 10 may include at least four axles, and may include five axles in various embodiments herein.

The prime mover 20 may be configured to use a variety of fuels (e.g., gasoline, diesel, biodiesel, ethanol, natural gas, compressed natural gas, hydrogen, fuel gas, etc.), according to various exemplary embodiments. According to an alternative embodiment, the prime mover 20 includes one or more electric motors coupled to the frame 12. The electric motors may consume electrical power from an on-board storage device (e.g., batteries, ultra-capacitors, hydrogen cells, etc.), from an on-board generator (e.g., an internal combustion engine, high efficiency solar panels, regenerative braking system, etc.), or from an external power source (e.g., overhead power lines) and provide power to the systems of the refuse vehicle 10. According to some embodiments, the refuse vehicle 10 may be in other configurations than shown in FIG. 1.

According to an exemplary embodiment, the refuse vehicle 10 is configured to transport refuse from various waste refuse containers within a municipality to a storage or processing facility (e.g., a landfill, an incineration facility, a recycling facility, etc.). The body 14 includes an on-board refuse container. In the embodiment of FIG. 1, the body 14 and on-board refuse container, in particular, defines a refuse compartment 30. In some embodiments, the body 14 includes a plurality of panels, shown as panels 32, a tailgate 34, and a cover 36 that together define the refuse compartment 30. Loose refuse may be placed into the refuse compartment 30 where it may thereafter be compacted (e.g., by a packer system, etc.). The refuse compartment 30 may provide temporary storage for refuse during transport to a waste disposal site and/or a recycling facility. In some embodiments, at least a portion of the body 14 and the refuse compartment 30 extend above or in front of the cab 16. According to the embodiment shown in FIG. 1, the body 14 and the refuse compartment 30 are positioned behind the cab 16.

In some embodiments, the refuse compartment 30 includes a hopper volume and a storage volume. Refuse may be initially loaded into the hopper volume and thereafter compacted into the storage volume. According to an exemplary embodiment, the hopper volume is positioned between the storage volume and the cab 16 (e.g., refuse is loaded into a position of the refuse compartment 30 behind the cab 16 and stored in a position further toward the rear of the refuse compartment 30). In such arrangements, the refuse vehicle 10 may be a front-loading refuse vehicle or a side-loading refuse vehicle. In other embodiments, the storage volume is positioned between the hopper volume and the cab 16. In such embodiments, the refuse vehicle 10 may be a rear-loading refuse vehicle in which refuse is loaded into the vehicle through a tailgate 34 or rear end of the vehicle.

The body 14 further includes a tailgate 34 which is movably (e.g., rotatably, etc.) coupled to the on-board refuse container and is positioned at the rear end of the body 14. The tailgate 34 is configured to pivot about pivot pins positioned along the top surface of the on-board refuse container. In other embodiments, a different connection mechanism may be used to support the tailgate 34 on the body 14.

As shown in FIG. 1, the refuse vehicle 10 includes a lift mechanism/system (e.g., a front-loading lift assembly, etc.), shown as lift assembly 40, coupled to the front end of the body 14. In other embodiments, the lift assembly 40 extends rearward of the body 14 (e.g., a rear-loading refuse vehicle, etc.). In still other embodiments, the lift assembly 40 extends from a side of the body 14 (e.g., a side-loading refuse vehicle, etc.). As shown in FIG. 1, the lift assembly 40 is configured to engage a container (e.g., a residential trash receptacle, a commercial trash receptacle, a container having a robotic grabber arm, etc.), shown as refuse container 50. The lift assembly 40 may include various actuators (e.g., electric actuators, hydraulic actuators, pneumatic actuators, etc.) to facilitate engaging the refuse container 50, lifting the refuse container 50, and tipping refuse out of the refuse container 50 into the hopper volume of the refuse compartment 30 through an opening in the cover 36 or through the tailgate 34. The lift assembly 40 may thereafter return the empty refuse container 50 to the ground. According to an exemplary embodiment, a door, shown as top door 38, is movably coupled along the cover 36 to seal the opening thereby preventing refuse from escaping the refuse compartment 30 (e.g., due to wind, bumps in the road, etc.).

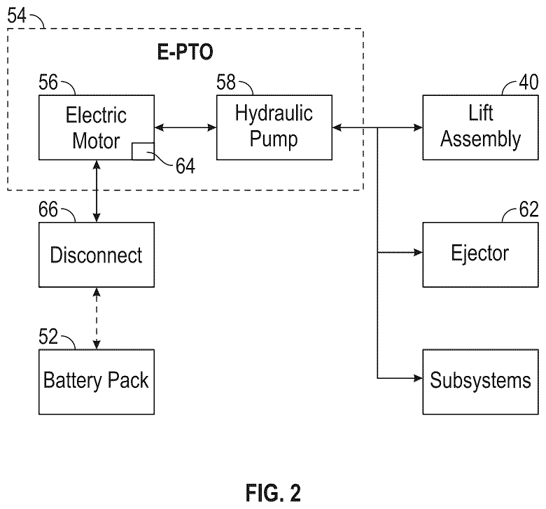

Referring to FIG. 2, in embodiments in which the refuse vehicle 10 is an electric refuse vehicle (e.g., an E-refuse vehicle, etc.) or a hybrid refuse vehicle (e.g., a vehicle including both electric and non-electric power systems, etc.), the refuse vehicle may further include an onboard energy storage device. In some embodiments, the onboard energy storage device includes a battery 52 that provides power to a motor that produces rotational power to drive the refuse vehicle. The energy storage device can be used to provide power to different subsystems on the refuse vehicle. The refuse vehicle may also include an electric power take-off (E-PTO) system, shown as E-PTO system 54, that is configured to receive electrical power from the battery 52 and/or other power sources and to convert the electrical power to hydraulic power for different subsystems on the refuse vehicle 10. In some embodiments, the E-PTO system 54 receives electrical power from the energy storage device and provides the electrical power to an electric motor 56. In such embodiments, the electric motor 56 may drive a hydraulic pump 58 that provides pressurized hydraulic fluid to different vehicle subsystems, such as the lift assembly 40, the packer/ejector, shown as ejector 62, or other subsystems (e.g., the tailgate, etc.).

The E-PTO system may include an E-PTO controller 64. The E-PTO controller 64 may monitor various systems within the refuse vehicle, including the E-PTO system 54. The E-PTO controller 64 may receive data from sensors (not shown) within the system, compare the data to expected values under normal operating conditions, adjust the operation parameters of components of the system, and determine if a critical operating condition exists based on the sensor data. Further, the E-PTO controller 64 may shut down the system and/or the refuse vehicle in response to detecting a critical operating condition. In some embodiments, the refuse vehicle further includes a disconnect 66 positioned between the battery 52 and the E-PTO system 54 to allow different vehicle subsystems (e.g., the ejector 62, the lift assembly 40, etc.) to be decoupled and de-energized from the electrical power source. For example, the E-PTO controller 64 may cause the disconnect 66 to be decoupled and de-energized from the electrical power source.

As shown in FIGS. 1-3, in embodiments in which the refuse vehicle 10 is a hybrid refuse vehicle (e.g., a vehicle including both fuel gas and electric power systems, a vehicle including natural gas and electric power systems, a vehicle including hydrogen gas and electric power systems, a vehicle including hydrogen fuel cell and electric power systems, etc.), the refuse vehicle may include a plurality of onboard storage devices. Each of the onboard storage devices may be configured to store material and/or energy that may be used to operate the systems of the refuse vehicle 10.

Although embodiments disclosed herein are described with reference to a refuse vehicle, it should be understood that the fueling and charging systems and methods of the present disclosure may also be used on other vocational vehicles including, but not limited to, cement trucks (e.g., mixer vehicles), dump trucks, and other on and off-highway vehicles having hydraulically actuated systems.

As shown in FIGS. 1-3, one of the onboard storage devices of the refuse vehicle 10 is a gas storage tank 70 (e.g., a gas cylinder, a gas vessel, a gas container, a fuel gas tank, etc.) configured to store the fuel gas utilized to power the systems of the refuse vehicle 10, according to some embodiments. In some embodiments, the onboard storage devices include a plurality of the gas storage tanks 70. For example, for a natural gas powered refuse vehicle, the gas storage tank 70 may be configured to store natural gas (e.g., methane, compressed natural gas (CNG), etc.) and provide the natural gas to the prime mover 20 (e.g., when the prime mover 20 is configured to use natural gas to provide power the systems of the refuse vehicle 10, etc.) and/or to the on-board generator of the refuse vehicle 10 (e.g., when the on-board generator is configured to use natural gas to generate electricity to provide power the systems of the refuse vehicle 10, etc.). As another example, for a hydrogen gas powered refuse vehicle, the gas storage tank 70 may be configured to store hydrogen gas and provide the hydrogen gas to the prime mover 20 (e.g., when the prime mover 20 is configured to use hydrogen gas to provide power the systems of the refuse vehicle 10, etc.) and/or to the on-board generator of the refuse vehicle 10 (e.g., when the on-board generator is configured to use hydrogen gas to generate electricity to provide power the systems of the refuse vehicle 10, etc.). As yet another example, for a hydrogen fuel cell powered refuse vehicle, the gas storage tank 70 may be configured to store hydrogen gas and provide the hydrogen gas to the on-board generator of the hydrogen cells which are configured to use the hydrogen gas to provide power to the systems of the refuse vehicle 10.

In other embodiments, the onboard storage devices include a liquid storage tank that stores liquid utilized to power the systems of the refuse vehicle 10. For example, for a liquid powered refuse vehicle, the liquid storage tank may be configured to store fuel gases in a liquid form (e.g., liquid hydrogen, liquid natural gas (LNG), etc.) that provides the liquids to the prime mover 20 (e.g., when the prime mover 20 is configured to use liquid hydrogen and/or liquid natural gas to provide power the systems of the refuse vehicle 10, etc.) and/or to the on-board generator of the refuse vehicle 10 (e.g., when the on-board generator is configured to use liquid hydrogen and/or liquid natural gas to generate electricity to provide power the systems of the refuse vehicle 10, etc.).

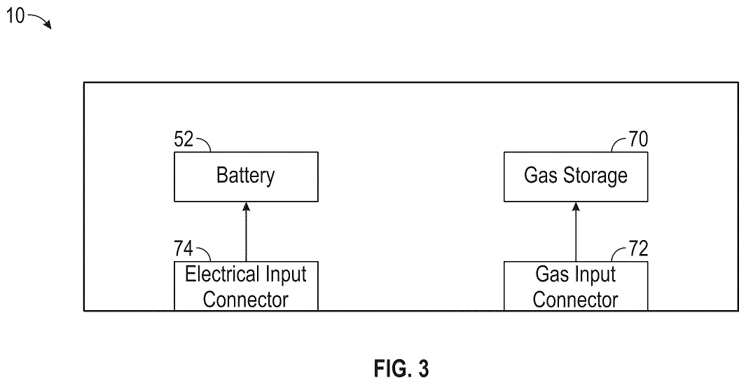

As shown in FIGS. 2 and 3, refuse vehicle 10 includes a gas input connector 72 fluidly coupled to a storage portion of the gas storage tank 70 and configured to receive fuel gas from an external gas source (e.g., a gas supply, an external gas tank, a refueling station, etc.), according to some embodiments. The gas input connector 72 may be configured as a gas inlet coupler configured to couple to a gas supply coupler of the external gas source in order to receive the fuel gas from the external gas source. For example, the gas input connector 72 may be configured as the gas inlet coupler configured to interface with the gas supply coupler of the external gas source to form an airtight connection such that the fuel gas being transferred from the external gas source to the gas storage tank 70 does not leak into the atmosphere (e.g., does not leak past the connection between the gas inlet coupler and the gas supply coupler, etc.).

As shown in FIGS. 1-3, one of the onboard storage devices of the refuse vehicle 10 is the battery 52 (e.g., a battery pack, a battery assembly, a battery cell, etc.) configured to store electricity utilized to power the systems of refuse vehicle 10, according to some embodiments. In some embodiments, the onboard storage devices include a plurality of the batteries 52 that store electricity utilized to power the systems of the refuse vehicle 10. The battery 52 may be configured to receive electricity from the prime mover 20 and/or the on-board generator of refuse vehicle 10. For example, when the refuse vehicle 10 is configured as a hybrid refuse vehicle that includes both fuel gas and electric power systems, an on-board generator configured to generate electricity by combusting natural gas may provide the electricity generated by the on-board generator to the battery 52 for storage and future use in powering the systems of the refuse vehicle 10. In some embodiments, the battery 52 may be configured to provide power to the E-PTO system 54 to generate hydraulic power for different subsystems of the refuse vehicle 10.

In some embodiments, the battery 52 may be configured to increase a range of the refuse vehicle 10 that includes the gas storage tank 70 configured to store the fuel gas utilized to power the systems of the refuse vehicle 10. For example, during a route (e.g., a refuse collection route, a collection route, etc.), the refuse vehicle 10 may utilize the fuel gas stored in the gas storage tank 70 to power the systems of the refuse vehicle 10 along a first portion of the route. Once the gas storage tank 70 has been emptied of the fuel gas, the refuse vehicle 10 may utilize the electricity stored in the battery 52 to power the systems of the refuse vehicle 10 along a second portion of the route. The second portion of the route may be equivalent to the increase in the range of the refuse vehicle 10 from the battery 52. In other embodiments, the gas storage tank 70 may be configured to increase the range of the refuse vehicle 10 that includes the battery 52 configured to store the electricity utilized to power the systems of the refuse vehicle 10. For example, during a route, the refuse vehicle 10 may utilize the electricity stored in the battery 52 to power the systems of the refuse vehicle 10 along a first portion of the route. Once the battery 52 has been depleted of electricity, the refuse vehicle 10 may utilize the fuel gas stored in the gas storage tank 70 to power the systems of the refuse vehicle 10 along a second portion of the route. The second portion of the route may be equivalent to the increase in the range of the refuse vehicle 10 from the gas storage tank 70.

As shown in FIG. 3, the refuse vehicle 10 includes an electrical input connector 74 (e.g., a port, a socket, etc.) electrically coupled to an electrical storage portion of the battery 52 and configured to receive electricity from an external electrical source (e.g., an electrical supply, an external battery, a recharging station, etc.), according to some embodiments. The electrical input connector 74 may be configured as an electrical inlet coupler configured to couple to an electrical supply coupler of the external electrical source in order to receive the electricity from the external electrical source. For example, the electrical input connector 74 may be configured as the electrical inlet coupler configured to interface with the electrical supply coupler of the external electrical source to form an electrically tight connection such that the electricity being transferred from the external electrical source does not escape the electrically tight connection.

### Integrated Fueling and Charging System

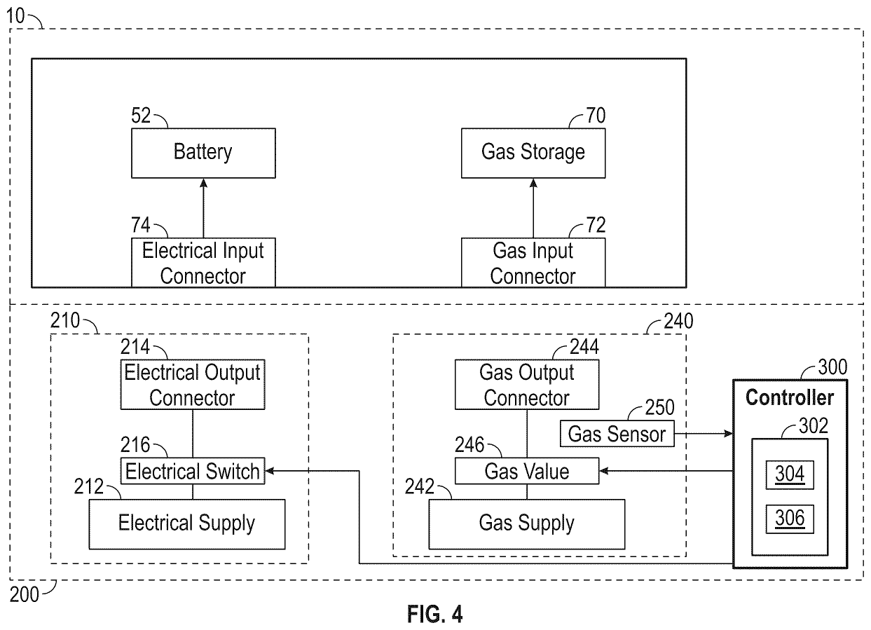

As shown in FIG. 4, an integrated fueling and charging system 200 (e.g., a gas and electrical fueling system, a hybrid fueling system, an integrated fueling station, a fuel gas and electrical fueling system, etc.) is configured to provide fuel and electricity to the refuse vehicle 10, according to some embodiments. In some embodiments the integrated fueling and charging system 200 may be included in a fueling and/or charging station associated with an owner of the refuse vehicle 10 configured to fuel and charge the refuse vehicle 10. For example, the integrated fueling and charging system 200 may be included in a fueling and/or charging station located at a refuse unloading site such that the refuse vehicle 10 can unload refuse supported by the refuse vehicle 10 and receive fuel and electricity from the integrated fueling and charging system 200 at the same location. In other embodiments, the integrated fueling and charging system 200 may be operated by another operator other than the owner of the refuse vehicle 10.

As shown in FIG. 4, the integrated fueling and charging system 200 includes an electrical supply system 210 (e.g., a charging system, a power system, a recharging system, etc.) configured to supply electricity to the battery 52 of the refuse vehicle 10, according to some embodiments. For example, the electrical supply system 210 may be configured to supply a flow of electricity to the refuse vehicle 10 to charge the battery 52 of the refuse vehicle 10 such that the electricity stored in the battery 52 may be used by the refuse vehicle 10 to power the systems of the refuse vehicle 10.

As shown in FIG. 4, the electrical supply system 210 includes an electrical supply 212 (e.g., a battery, an electrical grid, an electrical generator, etc.) that provides the electricity supplied to the refuse vehicle 10, according to some embodiments. For example, the electrical supply 212 may be connected to a local grid (e.g., a system supplied electricity from an electrical power plant, etc.) that supplies the electricity to the electrical supply 212. In some embodiments, the electrical supply 212 is configured to generate electricity that is supplied to the refuse vehicle 10. For example, the electrical supply 212 may include a solar panel configured to generate electricity from the sun, a wind turbine configured to be driven by the wind to generate electricity, or a generator configured to combust a fuel to generate electricity.

As shown in FIG. 4, the electrical supply system 210 includes an electrical output connector 214 (e.g., a plug, a jack, etc.) electrically coupled to the electrical supply 212, according to some embodiments. The electrical output connector 214 is configured to engage (e.g., couple with, be received by, etc.) the electrical input connector 74 of the refuse vehicle 10 to electrically couple the electrical supply 212 to the battery 52 of the refuse vehicle 10 to supply electricity from the electrical supply 212 to the battery 52. For example, the electrical output connector 214 may define a plurality of prongs (e.g., forks, posts, etc.) configured to extend into a plurality of apertures defined by the electrical input connector 74 to electrically couple the electrical supply 212 to the battery 52. As another example, the electrical output connector 214 may be configured as a male quick disconnect terminal configured to be inserted into a female quick disconnect terminal defined by the electrical input connector 74 to electrically couple the electrical supply 212 to the battery 52.

As shown in FIG. 4, the electrical supply system 210 includes an electrical switch 216 (e.g., a switch, a power switch, a disconnect switch, etc.) configured to control a flow of the electricity between the electrical supply 212 and the electrical output connector 214, according to some embodiments. The electrical switch 216 may be used to control the flow of the electricity between the electrical supply 212 and the battery 52 of the refuse vehicle 10 when the electrical output connector 214 is electrically coupled to the electrical input connector 74 of the refuse vehicle 10. In some embodiments, the electrical switch 216 may include different configurations that control the flow of the electricity between the electrical supply 212 and the electrical output connector 214. For example, the electrical switch 216 may include a first configuration (e.g., an on configuration, etc.) that allows the flow of the electricity between the electrical supply 212 and the electrical output connector 214 and a second configuration (e.g., an off configuration, etc.) that does not allow the flow of the electricity between the electrical supply 212 and the electrical output connector 214 (e.g., that causes the electrical output connector 214 to be decoupled and de-energized from the electrical supply 212, etc.). The electrical switch 216 may also include an intermediate configuration that allows the flow of the electricity between the electrical supply 212 and the electrical output connector 214 at a lower rate than the first configuration. In some embodiments, the electrical switch 216 may include a manual control input (e.g., an emergency stop, etc.) configured to be operated by an operator of the integrated fueling and charging system 200 and/or the refuse vehicle 10 to allow or not allow the flow of the electricity between the electrical supply 212 and the electrical output connector 214.

In some embodiments, the electrical output connector 214 is configured to form an electrical interlock loop with the electrical input connector 74 of the refuse vehicle 10 when the electrical output connector 214 is received by the electrical input connector 74 to prevent the flow of electricity from the electrical supply 212 to the battery 52 of the refuse vehicle 10 under certain conditions. For example, when the electrical output connector 214 is received by the electrical input connector 74, a low voltage electrical loop may be formed, with a portion of the low voltage electrical loop positioned between the electrical output connector 214 and the electrical input connector 74. A low voltage of the low voltage electrical loop may be lower than a voltage of the flow of electricity from the electrical supply 212 to the battery 52. If the low voltage electrical loop between the electrical output connector 214 and the electrical input connector 74 is interrupted, it may be an indication that there is an issue with an electrical connection between the electrical output connector 214 and the electrical input connector 74. In some embodiments, the electrical output connector 214 is configured to disconnect from the electrical input connector 74 when the low voltage electrical loop is interrupted such that the flow of electricity from the electrical supply 212 to the battery 52 is stopped.

In some embodiments, the electrical output connector 214 is configured to form a two-step connection with the electrical input connector 74 when the electrical output connector 214 is received by the electrical input connector 74. When disconnecting the two-step connection, first an operator interrupts the flow of electricity between the electrical output connector 214 and the electrical input connector 74 and then separates the electrical output connector 214 from the electrical input connector 74. The configuration of the two-step connection may ensure that the electricity is not flowing between the electrical output connector 214 and the electrical input connector 74 when the electrical output connector 214 is separated from the electrical input connector 74.

In some embodiments, the electrical output connector 214 is configured as a fuse-in connector configured to interrupt the flow of the electricity between the electrical output connector 214 and the electrical input connector 74 when a current of the flow of the electricity is above a current threshold. As a fuse-in connector, the electrical output connector 214 may stop the flow of the electricity when the current of the flow of the electricity is above the current threshold to prevent damage to the electrical output connector 214, the electrical input connector 74, and/or the battery 52.

As shown in FIG. 4, the integrated fueling and charging system 200 includes a gas supply system 240 (e.g., a gas fueling system, a gassing system, a refueling system, etc.) configured to supply fuel gas to the refuse vehicle 10, according to some embodiments. For example, the gas supply system 240 may be configured to supply a flow of fuel gas to the refuse vehicle 10 to fill the gas storage tank 70 of the refuse vehicle 10 such that the fuel gas stored in the gas storage tank 70 may be used by the on-board generator of the refuse vehicle 10 to generate electricity to power the systems of the refuse vehicle 10.

As shown in FIG. 4, the gas supply system 240 includes a gas supply 242 (e.g., a gas reservoir, a natural gas supply, a hydrogen supply, a gas pipeline, etc.) that provides the fuel gas supplied to the refuse vehicle 10, according to some embodiments. For example, the gas supply 242 may be connected to a local gas network (e.g., a gas pipeline, a natural gas pipeline, etc.) that supplies the fuel gas to the gas supply 242. As another example, the gas supply 242 may be a large gas tank (e.g., larger than the gas storage tank 70, etc.) that may be filled with fuel gas (e.g., from a supply truck, etc.).

As shown in FIG. 4, the gas supply system 240 includes a gas output connector 244 (e.g., a fitting, a coupling, a connector hose, etc.) fluidly coupled to the gas supply 242, according to some embodiments. The gas output connector 244 is configured to engage (e.g., couple to, be received by, etc.) the gas input connector 72 of the refuse vehicle 10 to fluidly couple the gas supply 242 to the gas storage tank 70 of the refuse vehicle 10 to supply fuel gas from the gas supply 242 to the gas storage tank 70. For example, the gas output connector 244 may be configured as a male quick-connect coupling configured to couple to a female quick-connect coupling of the gas input connector 72 to fluidly couple the gas supply 242 to the gas storage tank 70. As another example, the gas output connector 244 may be define male threads configured to engage female threads defined by the gas input connector 72 to fluidly couple the gas supply 242 to the gas storage tank 70.

As shown in FIG. 4, the gas supply system 240 includes a gas valve 246 (e.g., a valve, a flow valve, etc.) configured to control a flow of the fuel gas between the gas supply 242 and the gas output connector 244, according to some embodiments. The gas valve 246 may be used to control the flow of the fuel gas between the gas supply 242 and the gas storage tank 70 of the refuse vehicle 10 when the gas output connector 244 is fluidly coupled to the gas input connector 72 of the refuse vehicle 10. In some embodiments, the gas valve 246 may include different configurations that control the flow of the gas between the gas supply 242 and the gas output connector 244. For example, the gas valve 246 may include a first configuration (e.g., a flow configuration, etc.) that allows the flow of the fuel gas between the gas supply 242 and the gas output connector 244 and a second configuration (e.g., a no flow configuration, etc.) that does not allow the flow of the fuel gas between the gas supply 242 and the gas output connector 244. The gas valve 246 may also include an intermediate configuration that allows the flow of the fuel gas between the gas supply 242 and the gas output connector 244 at a lower rate than the first configuration. In some embodiments, the gas valve 246 may include a manual control input configured to be operated by an operator of the integrated fueling and charging system 200 and/or the refuse vehicle 10 to allow or not allow the flow of the fuel gas between the gas supply 242 and the gas output connector 244.

As shown in FIG. 4, the gas supply system 240 includes a gas sensor 250 (e.g., a gas detector, a gas monitor, a gas probe, etc.) configured to detect a presence of the fuel gas provided by the gas supply 242, according to some embodiments. The gas sensor 250 may determine if a concentration of the fuel gas provided by the gas supply 242 is above a fuel gas threshold. In some embodiments, the gas sensor 250 is configured to generate sensor data based on the presence of the fuel gas provided by the gas supply 242. For example, the gas sensor 250 may be positioned proximate the gas output connector 244 and be configured to detect if the fuel gas flowing through the gas output connector 244 into the gas storage tank 70 is leaking between the gas output connector 244 and the gas input connector 72. The gas sensor 250 may generate sensor data corresponding to a leak of the fuel gas from the fluid connection between the gas output connector 244 and the gas input connector 72. In some embodiments, the gas sensor 250 may be configured as a chemical reaction sensor, an electrochemical sensor, a photoionization detector, an infrared absorption sensor, or another type of gas sensor configured to identify a presence of a target gas. In some embodiments, the gas supply system 240 includes a plurality of the gas sensors 250 configured to detect the presence of the fuel gas provided by the gas supply 242.

As shown in FIG. 4, the integrated fueling and charging system 200 includes a controller 300, according to some embodiments. The controller 300 includes processing circuitry 302 including a processor 304 and memory 306. Processing circuitry 302 can be communicably connected with a communications interface of controller 300 such that processing circuitry 302 and the various components thereof can send and receive data via the communications interface. Processor 304 can be implemented as a general purpose processor, an application specific integrated circuit (ASIC), one or more field programmable gate arrays (FPGAs), a group of processing components, or other suitable electronic processing components.

Memory 306 (e.g., memory, memory unit, storage device, etc.) can include one or more devices (e.g., RAM, ROM, Flash memory, hard disk storage, etc.) for storing data and/or computer code for completing or facilitating the various processes, layers and modules described in the present application. Memory 306 can be or include volatile memory or non-volatile memory. Memory 306 can include database components, object code components, script components, or any other type of information structure for supporting the various activities and information structures described in the present application. According to some embodiments, memory 306 is communicably connected to processor 304 via processing circuitry 302 and includes computer code for executing (e.g., by at least one of processing circuitry 302 or processor 304) one or more processes described herein.

The controller 300 is configured to receive inputs (e.g., measurements, detections, signals, sensor data, etc.) from the electrical supply system 210 and/or the gas supply system 240, according to some embodiments. In particular, the controller 300 may receive a configuration of the electrical switch 216 of the electrical supply system 210, a configuration of the gas valve 246 of the gas supply system 240, and/or sensor data from the gas sensor 250 corresponding to the presence of the fuel gas supplied by the gas supply 242 proximate the gas sensor 250. In some embodiments, the controller 300 is configured to receive inputs from the refuse vehicle 10 (e.g., when the refuse vehicle 10 is being fueled and/or charged by the integrated fueling and charging system 200, etc.). For example, the controller 300 may receive a charge level indication from the refuse vehicle 10 corresponding to a charge level of the battery 52 and/or a fuel level indication from the refuse vehicle 10 corresponding to a fill level of the gas storage tank 70. In some embodiments, the controller 300 may receive user inputs from a user interface (e.g., from a display screen, from an interface panel, etc.). For example, the user inputs may be button presses from a button of a user interface.

The controller 300 may be configured to provide control outputs (e.g., control decisions, control signals, etc.) to the electrical supply system 210 and/or the gas supply system 240 to operate the electrical supply system 210 and/or the gas supply system 240 to control the flow of the electricity outputted by the electrical supply system 210 and/or the flow of the fuel gas outputted by the gas supply system 240. For example, the controller 300 may provide a control output to the electrical switch 216 to operate the electrical switch 216 control the flow of the electricity from the electrical supply 212 to the electrical output connector 214. The controller 300 may provide the control output to the electrical switch 216 to operate the electrical switch 216 to cease providing the flow of the electricity from the electrical output connector 214 to the electrical input connector 74 in response to receiving an indication of a failure of the electrical connection between the electrical output connector 214 and the electrical input connector 74. As another example, the controller 300 may provide a control output to the gas valve 246 to control the flow of the fuel gas from the gas supply 242 to the gas output connector 244. The controller 300 may provide the control output to the gas valve 246 to operate the gas valve 246 to cease providing the flow of the fuel gas from the gas output connector 244 to the gas input connector 72 in response to receiving an indication of a failure of the fluid connection between the gas output connector 244 and the gas input connector 72. In some embodiments, the controller 300 is configured to operate an alert system of the integrated fueling and charging system 200 (e.g., lights, speakers, display screens, etc.) to provide one or more aural or visual alerts to nearby individuals based on the operation of the integrated fueling and charging system 200. For example, the controller 300 may operate the alert system to provide an alert when the sensor data received from the gas sensor 250 indicates the presence of the fuel gas provided by the gas supply 242 proximate the gas sensor 250.

In some embodiments, the controller 300 is configured to provide control outputs to the electrical switch 216 to operate the electrical switch 216 to stop the flow of electricity from the electrical supply 212 to the battery 52 of the refuse vehicle 10 after receiving an indication that the low voltage electrical loop between the electrical output connector 214 and the electrical input connector 74 has been interrupted (e.g., an indication of a failure of the electrical connection between the electrical output connector 214 and the electrical input connector 74, etc.). For example, the controller 300 may operate the electrical switch 216 to stop the flow of electricity through the electrical output connector 214 in response to receiving the indication that the low voltage electrical loop between the electrical output connector 214 and the electrical input connector 74 has been interrupted to prevent sparks from being emitted between the electrical output connector 214 and the electrical input connector 74 if the electrical output connector 214 is improperly received by the electrical input connector 74. In some embodiments, the controller 300 is configured to provide control outputs to the gas valve 246 to operate the gas valve 246 to stop the flow of fuel gas from the gas supply 242 to the gas storage tank 70 of the refuse vehicle 10 after receiving an indication that the low voltage electrical loop between the electrical output connector 214 and the electrical input connector 74 has been interrupted.

In some embodiments, the controller 300 is configured to provide control outputs to the gas valve 246 to operate the gas valve 246 to stop the flow of fuel gas from the gas supply 242 to the gas storage tank 70 of the refuse vehicle 10 after receiving sensor data from the gas sensor 250 indicating the presence of the fuel gas provided by the gas supply 242 proximate the gas sensor 250 (e.g., an indication of a failure of the fluid connection between the gas output connector 244 and the gas input connector 72, etc.). For example, the controller 300 may operate the gas valve 246 to cease providing the flow of fuel gas through the gas output connector 244 to the gas input connector 72 in response to receiving the sensor data indicating that the leak of fuel gas from the fluid connection between the gas output connector 244 and the gas input connector 72 exceeds a fuel gas leakage threshold to prevent additional fuel gas from leaking between the gas output connector 244 and the gas input connector 72 if the gas output connector 244 is improperly received by the gas input connector 72. In some embodiments, the controller 300 is configured to provide control outputs to the electrical switch 216 to operate the electrical switch 216 to stop the flow of electricity from the electrical supply 212 to the battery 52 of the refuse vehicle 10 after receiving sensor data from the gas sensor 250 indicating the presence of the fuel gas provided by the gas supply 242 proximate the gas sensor 250.

The controller 300 may also be configured to receive feedback from any of the electrical supply system 210, the gas supply system 240, or the refuse vehicle 10. For example, the controller 300 may receive feedback from the electrical supply system 210 associated with a configuration of the electrical switch 216, an electrical supply quantity of the electricity available to the electrical supply 212, an electrical connection status between the electrical output connector 214 and the electrical input connector 74 of the refuse vehicle 10, etc. As another example, the controller may receive feedback from the gas supply system 240 associated with a configuration of the gas valve 246, a gas supply quantity of the fuel gas available to the gas supply 242, a gas connection status between the gas output connector 244 and the gas input connector 72 of the refuse vehicle 10, etc. In some embodiments, the controller 300 is configured to generate additional control outputs based on the feedback received by the controller 300. For example, if the controller 300 receives feedback from the electrical supply system 210 that the electrical connection between the electrical output connector and the electrical input connector 74 is failing, the controller 300 may generate control outputs for the electrical switch 216 to operate the electrical switch 216 to stop the flow of electricity from the electrical supply 212 to the battery 52 of the refuse vehicle 10.

In some embodiments, the controller 300 is configured to perform a startup sequence (e.g., an initialization, a start test, a validation test, etc.) of the integrated fueling and charging system 200. The startup sequence may include performing an electrical connection test (e.g., a first connection test, etc.) on an electrical connection (e.g., a first connection, etc.) between the electrical output connector 214 and the electrical input connector 74 and a gas connection test (e.g., a second connection test, etc.) on a gas connection (e.g., a second connection, etc.) between the gas output connector 244 and the gas input connector 72. For example, the startup sequence may include sequentially performing the electrical connection test and the gas connection test. In some embodiments, the controller 300 is configured to operate the integrated fueling and charging system 200 to perform the electrical connection test on the electrical connection between the electrical output connector 214 and the electrical input connector 74 prior to performing the gas connection test on the gas connection between the gas output connector 244 and the gas input connector 72. In other embodiments, the controller 300 is configured to operate the integrated fueling and charging system 200 to perform the gas connection test on the gas connection between the gas output connector 244 and the gas input connector 72 prior to performing the electrical connection test on the electrical connection between the electrical output connector 214 and the electrical input connector 74. In some embodiments, the controller 300 is configured to not simultaneously perform the gas connection test on the gas connection and the electrical connection test on the electrical connection. For example, the controller 300 may not simultaneously perform the gas connection test on the gas connection and the electrical connection test on the electrical connection because sparks that are emitted by a bad electrical connection could ignite fuel gas leaking from an improper gas connection (e.g., a leaking gas connection, a bad gas connection, an inadequate gas connection, etc.).

In some embodiments, to perform the electrical connection test on the electrical connection between the electrical output connector 214 and the electrical input connector 74, the controller 300 is configured to provide control outputs to the electrical switch 216 to operate the electrical switch 216 to provide the flow of electricity from the electrical supply 212 to the electrical input connector 74 with a low current. For example, the controller 300 may provide a control output to the electrical switch 216 to provide the flow of electricity from the electrical supply 212 to the electrical interlock loop between the electrical output connector 214 and the electrical input connector 74. The electrical connection may pass the electrical connection test if the low voltage electrical loop is formed in the electrical interlock loop. In other embodiments, the controller 300 is configured to otherwise operate the electrical supply system 210 to verify the electrical connection between the electrical output connector 214 and the electrical input connector 74 (e.g., receive sensor data from an electrical connector sensor configured provide indications associated with the electrical connection, etc.).

In some embodiments, to perform the gas connection test on the gas connection between the gas output connector 244 and the gas input connector 72, the controller 300 is configured to provide control outputs to the gas valve 246 to operate the gas valve 246 to provide the flow of fuel gas from the gas supply 242 to the gas input connector 72 with a low flow rate. For example, the controller 300 may provide a control output to the gas valve 246 to provide the flow of fuel gas from the gas supply 242 to the gas output connector 244. The gas connection may pass the gas connection test if the gas sensor 250 does not sense the presence of the fuel gas proximate the gas sensor 250 when the fuel gas with the low flow rate is flowing through the gas connection. In other embodiments, the controller 300 is configured to otherwise operate the gas supply system 240 to verify the gas connection between the gas output connector 244 and the gas input connector 72 (e.g., receive sensor data from a gas connector sensor configured to provide indications associated with the gas connection, etc.).

The controller 300 is configured to initiate a fueling and charging process of the integrated fueling and charging system 200 after determining that the electrical connection between the electrical output connector 214 and the electrical input connector 74 passes the electrical connection test and that the gas connection between the gas output connector 244 and the gas input connector 72 passes the gas connection test, according to some embodiments. The fueling and charging process of the integrated fueling and charging system 200 may include operating the integrated fueling and charging system 200 to simultaneously provide fuel gas from the gas supply 242 to the gas storage tank 70 (e.g., through the gas output connector 244 and the gas input connector 72, etc.) and provide electricity from the electrical supply 212 to the battery 52 (e.g., through the electrical output connector 214 and the electrical input connector 74, etc.). For example, the controller 300 may provide a first control output to the electrical switch 216 to operate the electrical switch 216 to allow the flow of electricity between the electrical supply 212 and the electrical output connector 214 and provide a second control output to the gas valve 246 to operate the gas valve 246 to allow the flow of fuel gas between the gas supply 242 and the gas output connector 244 such that the flow of electricity is provided to the battery 52 and the flow of fuel gas is provided to the gas storage tank 70 simultaneously.

The controller 300 may limit the fueling and charging process of the integrated fueling and charging system 200 after determining that at least one of the electrical connection between the electrical output connector 214 and the electrical input connector 74 failed the electrical connection test or the gas connection between the gas output connector 244 and the gas input connector 72 failed the gas connection test, according to some embodiments. For example, after determining that at least one of the electrical connection failed the electrical connection test or the gas connection failed the gas connection test, the controller 300 may provide control outputs to the electrical switch 216 to stop the flow of electricity through the electrical switch 216 and the gas valve 246 to stop the flow of fuel gas through the gas valve 246. In other embodiments, the controller 300 may limit the fueling and charging process of the integrated fueling and charging system 200 after determining that both the electrical connection between the electrical output connector 214 and the electrical input connector 74 fails the electrical connection test and the gas connection between the gas output connector 244 and the gas input connector 72 fails the gas connection test.

The controller 300 is configured to initiate a limited fueling and charging process of the integrated fueling and charging system 200 after determining that at least one of the electrical connection fails the electrical connection test or the gas connection fails the gas connection test, according to some embodiments. The limited fueling and charging process of the integrated fueling and charging system 200 may include sequentially operating the electrical supply system 210 to provide the electricity to the refuse vehicle 10 and the gas supply system 240 to provide the fuel gas to the refuse vehicle 10. In some embodiments, the limited fueling and charging process of the integrated fueling and charging system 200 includes operating the electrical switch 216 to provide electricity from the electrical supply 212 until a charge of the battery 52 is above a charging threshold (e.g., the battery 52 is fully charged, etc.), operating the electrical switch 216 to stop the flow of electricity through the electrical switch 216, and subsequently operating the gas valve 246 to provide fuel gas from the gas supply 242 to the gas storage tank 70. In other embodiments, the limited fueling and charging process of the integrated fueling and charging system 200 includes operating the gas valve 246 to provide fuel gas from the gas supply 242 to the gas storage tank 70 until a quantity of fuel gas contained by the gas storage tank 70 is above a fill threshold (e.g., the gas storage tank 70 is full of gas, etc.), operating the gas valve 246 to stop the flow of fuel gas through the gas valve 246, and subsequently operating the electrical switch 216 to provide electricity from the electrical supply 212 to the battery 52.

In some embodiments, the controller 300 is configured to initiate the limited fueling and charging process of the integrated fueling and charging system 200 after receiving a user input from an operator the integrated fueling and charging system 200 and/or the refuse vehicle 10 associated with a manual override of the controller 300 limiting the fueling and charging process of the integrated fueling and charging system 200. For example, after limiting the fueling and charging process of the integrated fueling and charging system 200, the controller 300 may generate and provide a notification to a display indicating that the fueling and charging process has been limited. The operator may then provide a user input (e.g., press a button, etc.) associated with the manual override of the integrated fueling and charging system 200 that allows the controller 300 to initiate the limited fueling and charging process of the integrated fueling and charging system 200.

### Process for Operating an Integrated Fueling and Charging System

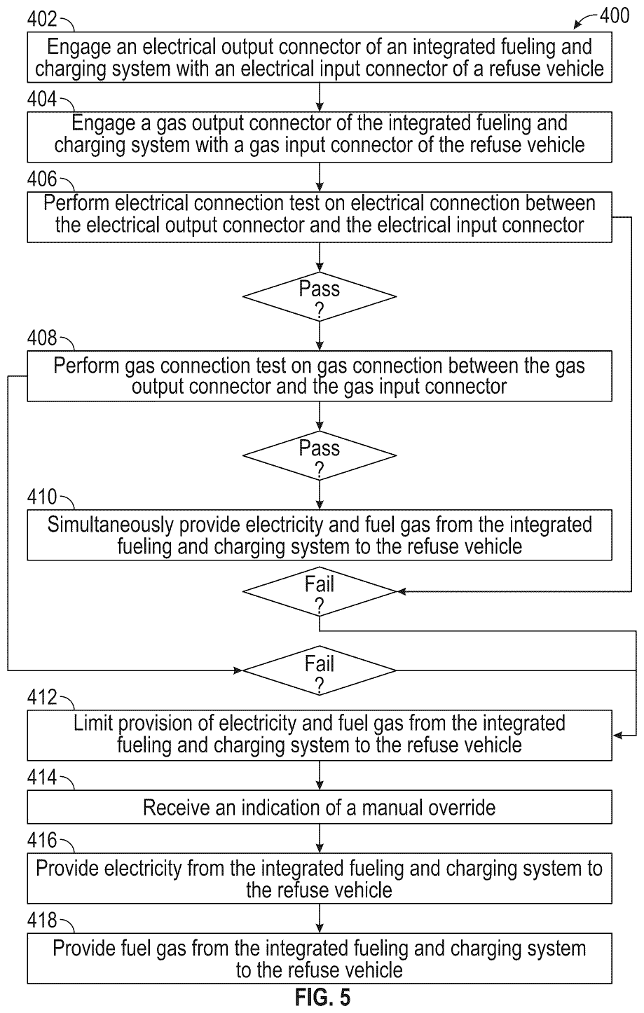

Referring to FIG. 5, a flow diagram of a process 400 for operating an integrated fueling and charging system (e.g., a method for operating a fueling and charging system, etc.) includes steps 402-418, according to some embodiments. In some embodiments, the process 400 is performed by the controller 300. The process 400 may be implemented in order to fuel and charge the refuse vehicle 10 using the integrated fueling and charging system 200. In some embodiments, the process 400 may be implemented in order to simultaneously and safely fuel the refuse vehicle 10 with fuel gas (e.g., gas, etc.) and charge the refuse vehicle 10 with electricity using the integrated fueling and charging system 200.

At step 402, the process 400 includes engaging an electrical output connector of an integrated fueling and charging system with an electrical input connector of a refuse vehicle, according to some embodiments. For example, the electrical output connector may include a plug that is received by a port of the electrical input connector to engage the electrical output connector with the electrical input connector. In some embodiments, the engagement of the electrical output connector and the electrical input connector may electrically couple the electrical output connector and the electrical input connector. For example, the engagement of the electrical output connector and the electrical input connector may form an electrical connection between the electrical output connector and the electrical input connector. In various embodiments, step 402 includes engaging the electrical output connector 214 of the integrated fueling and charging system 200 with the electrical input connector 74 of the refuse vehicle 10 to electrically couple the electrical output connector 214 and the electrical input connector 74.

At step 404, the process 400 includes engaging a gas output connector of the integrated fueling and charging system with a gas input connector of the refuse vehicle, according to some embodiments. For example, the gas output connector may define male threads configured to engage with female threads of the gas input connector to engage the gas output connector to the gas input connector. In some embodiments, the engagement of the gas output connector and the gas input connector may fluidly couple the gas output connector and the gas input connector. For example, the engagement of the gas output connector and the gas input connector may for a gas connection between the gas output connector and the gas input connector. In various embodiments, step 404 includes engaging the gas output connector 244 of the integrated fucling and charging system 200 with the gas input connector 72 of the refuse vehicle 10 to fluidly couple the gas output connector 244 and the gas input connector 72.

At step 406, the process 400 includes performing an electrical connection test on the electrical connection between the electrical output connector and the electrical input connector, according to some embodiments. For example, the electrical connection test on the electrical connection may include verifying that the electrical connection is well-secured. The electrical connection test may verify that electricity flowing through the electrical connection will not flow outside of the electrical connection (e.g., to an outside surface of the electrical connection, etc.). For example, the electrical connection test may verify that the electricity flowing through the electrical connection will not cause sparks to form outside of the electrical connection. In various embodiments, the electrical connection test of step 406 is performed on the electrical connection between the electrical output connector 214 and the electrical input connector 74. For example, the electrical connection test of step 406 may include verifying that a low voltage electrical loop is formed in an electrical interlock loop formed by the electrical output connector 214 and the electrical input connector 74.

If the electrical connection between the electrical output connector and the electrical input connector passes the electrical connection test (“PASS”), the process 400 proceeds to step 408, according to some embodiments. If the electrical connection between the electrical output connector and the electrical input connector fails the electrical connection test (“FAIL”), the process 400 proceeds to step 412, according to some embodiments.

At step 408, the process 400 includes performing a gas connection test on the gas connection between the gas output connector and the gas input connector, according to some embodiments. For example, the gas connection test on the gas connection may include verifying that the gas connection is well-secured. The gas connection test may verify that fuel gas flowing through the gas connection will not flow outside of the gas connection. For example, the gas connection test may verify that the gas connection does not have a leak that could allow for the fuel gas flowing through the gas connection to leak outside of the gas connection. In various embodiments, the gas electrical connection test of step 408 is performed on the gas connection between the gas output connector 244 and the gas input connector 72. For example, the gas connection test of step 408 may include verifying with the gas sensor 250 that fuel gas in not present outside of the gas connection when a low flow rate of fuel gas is provided through the gas connection. In various embodiments, the electrical connection test of step 406 and the gas connection test of step 408 are performed sequentially. For example, the electrical connection test of step 406 may be completed prior to performing the gas connection test of step 408.

In other embodiments, the gas connection test of step 408 is performed on the gas connection between the gas output connector 244 and the gas input connector 72. In other embodiments, an order of step 406 and step 408 may be swapped. That is, the process 400 may include performing the gas connection test of step 408 prior to performing the electrical connection test of step 406.

If the gas connection between the gas output connector and the gas input connector passes the gas connection test (“PASS”), the process 400 proceeds to step 410, according to some embodiments. If the gas connection between the gas output connector and the gas input connector fails the gas connection test (“FAIL”), the process 400 proceeds to step 412, according to some embodiments.

At step 410, the process 400 includes simultaneously providing electricity from the integrated fueling and charging system to the refuse vehicle and providing fuel gas from the integrated fueling and charging system to the refuse vehicle, according to some embodiments. For example, step 410 may include simultaneously providing electricity from an electrical source of the integrated fueling and charging system to a battery of the refuse vehicle and providing fuel gas from a gas source of the integrated fueling and charging system to a gas tank of the refuse vehicle. In various embodiments, step 410 includes simultaneously providing electricity from the integrated fueling and charging system 200 to the refuse vehicle 10 and providing fuel gas from the integrated fueling and charging system 200 to the refuse vehicle 10. For example, electricity may be provided from the electrical supply 212 of the electrical supply system 210 to the battery 52 of the refuse vehicle 10 and fuel gas may be provided from the gas supply 242 of the gas supply system 240 to the gas storage tank 70 of the refuse vehicle 10 simultaneous with the electricity provided from the electrical supply 212.

At step 412, the process 400 includes limiting provision of electricity and fuel gas from the integrated fueling and charging system to the refuse vehicle, according to some embodiments. Step 412 may be performed in response to at least one of the electrical connection failing the electrical connection test or the gas connection failing the gas connection test. For example, step 412 may include closing a switch between the electricity source of the integrated fueling and charging system and the electrical output connector to prevent the flow of electricity to the refuse vehicle and closing a valve between the gas supply of the integrated fueling and charging system and the gas output connector to prevent the flow of fuel gas to the refuse vehicle. In various embodiments, step 412 includes limiting the provision of electricity and fuel gas from the integrated fueling and charging system 200 to the refuse vehicle 10. For example, step 412 may include operating the electrical switch 216 of the electrical supply system 210 to prevent the flow of electricity between the electrical supply 212 and the battery 52 and operating the gas valve 246 of the gas supply system 240 to prevent the flow of fuel gas between the gas supply 242 and the gas storage tank 70.

At step 414, the process 400 includes receiving an indication of a manual override, according to some embodiments. The manual override may be associated with overriding the limitation of the provision of electricity and fuel gas from the integrated fueling and charging system to the refuse vehicle. For example, the controller 300 may receive an indication from a user interface corresponding to a manual override associated with proceeding with a limited fueling and charging process of the integrated fueling and charging system 200.

At step 416, the process 400 includes providing electricity from the integrated fueling and charging system to the refuse vehicle, according to some embodiments. In some embodiments, step 416 includes limiting the provision of fuel gas from the integrated fueling and charging system to the refuse vehicle while providing electricity from the integrated fucling and charging system to the refuse vehicle. For example, step 416 may include opening the switch between the electricity supply and the electrical output connector to allow the flow of electricity from the electrical supply to the refuse vehicle while keeping the valve between the gas supply and the gas output connector closed to prevent the flow of fuel gas to the refuse vehicle.

At step 418, the process 400 includes providing fuel gas from the integrated fueling and charging system to the refuse vehicle, according to some embodiments. In some embodiments, step 418 includes limiting the provision of electricity from the integrated fueling and charging system to the refuse vehicle while providing fuel gas from the integrated fueling and charging system to the refuse vehicle. For example, step 418 may include closing the switch between the electricity source and the electrical output connector to prevent the flow of electricity to the refuse vehicle while opening the valve between the gas source and the gas output connector to allow the flow of fuel gas between the gas supply and the refuse vehicle. In various embodiments, step 416 and step 418 are performed sequentially. For example, the process 400 may include completing the step 416 of providing electricity from the integrated fueling and charging system to the refuse vehicle prior to performing the step 418 of providing fuel gas from the integrated fueling and charging system to the refuse vehicle.

In other embodiments, an order of step 416 and step 418 may be swapped. That is, the process 400 may include providing the fuel gas from the integrated fueling and charging system to the refuse vehicle prior to providing the electricity from the integrated fueling and charging system to the refuse vehicle. For example, when the refuse vehicle primarily runs on the fuel gas, the fuel gas may be provided to the refuse vehicle prior to the electricity to allow for more rapid operation of the refuse vehicle.

As utilized herein with respect to numerical ranges, the terms “approximately,” “about,” “substantially,” and similar terms generally mean +/−10% of he disclosed values. When the terms “approximately,” “about,” “substantially,” and similar terms are applied to structural features (e.g., to describe its shape, size, orientation, direction, etc.), these terms are meant to cover minor variations in structure that may result from, for example, the manufacturing or assembly process and are intended to have a broad meaning in harmony with the common and accepted usage by those of ordinary skill in the art to which the subject matter of this disclosure pertains. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

The terms “coupled,” “connected,” and the like, as used herein, mean the joining of two members directly or indirectly to one another. Such joining may be stationary (e.g., permanent, etc.) or moveable (e.g., removable, releasable, etc.). Such joining may be achieved with the two members, or the two members and any additional intermediate members being integrally formed as a single unitary body with one another or with the two members or the two members and any additional intermediate members being attached to one another.

References herein to the positions of elements (e.g., “top,” “bottom,” “above,” etc.) are merely used to describe the orientation of various elements in the figures. It should be noted that the orientation of various elements may differ according to other exemplary embodiments, and that such variations are intended to be encompassed by the present disclosure.

The hardware and data processing components used to implement the various processes, operations, illustrative logics, logical blocks, modules and circuits described in connection with the embodiments disclosed herein may be implemented or performed with a general purpose single-or multi-chip processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general-purpose processor may be a microprocessor, or any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some embodiments, particular processes and methods may be performed by circuitry that is specific to a given function. The memory (e.g., memory, memory unit, storage device) may include one or more devices (e.g., RAM, ROM, Flash memory, hard disk storage) for storing data and/or computer code for completing or facilitating the various processes, layers and modules described in the present disclosure. The memory may be or include volatile memory or non-volatile memory, and may include database components, object code components, script components, or any other type of information structure for supporting the various activities and information structures described in the present disclosure. According to an exemplary embodiment, the memory is communicably connected to the processor via a processing circuit and includes computer code for executing (e.g., by the processing circuit or the processor) the one or more processes described herein.

The present disclosure contemplates methods, systems, and program products on any machine-readable media for accomplishing various operations. The embodiments of the present disclosure may be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general-purpose computer, special purpose computer, or special purpose processing machines to perform a certain function or group of functions.

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It is important to note that the construction and arrangement of the refuse vehicle as shown in the exemplary embodiments is illustrative only. Although only a few embodiments of the present disclosure have been described in detail, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts or elements. It should be noted that the elements and/or assemblies of the components described herein may be constructed from any of a wide variety of materials that provide sufficient strength or durability, in any of a wide variety of colors, textures, and combinations. Accordingly, all such modifications are intended to be included within the scope of the present disclosures. Other substitutions, modifications, changes, and omissions may be made in the design, operating conditions, and arrangement of the preferred and other exemplary embodiments without departing from scope of the present disclosure or from the spirit of the appended claims.

What is claimed is:

1. A method for operating an integrated fueling and charging system, the method comprising:
electrically coupling an electrical output of the integrated fueling and charging system with an electrical input of a vehicle;
fluidly coupling a gas output of the integrated fueling and charging system with a gas input of the vehicle;
performing a first connection test on a first connection between the electrical output and the electrical input;
performing a second connection test on a second connection between the gas output and the gas input; and
responsive to the first connection passing the first connection test and the second connection passing the second connection test, simultaneously providing electricity and fuel gas from the integrated fueling and charging system to the vehicle.

2. The method of claim 1, wherein the first connection test and the second connection test are performed sequentially.

3. The method of claim 1, further comprising:
responsive to at least one of the first connection failing the first connection test or the second connection failing the second connection test, sequentially providing the electricity and the fuel gas from the integrated fueling and charging system to the vehicle.

4. The method of claim 3, wherein prior to sequentially providing the electricity and the fuel gas the integrated fueling and charging system to the vehicle, the method further comprises:
receiving, from an operator of the integrated fueling and charging system, a user input associated with a manual override of the integrated fueling and charging system.

5. The method of claim 3, wherein when the electricity and the fuel gas are sequentially provided to the vehicle, the fuel gas is provided to the vehicle before the electricity is provided to the vehicle.

6. The method of claim 1, further comprising:
while simultaneously providing electricity and fuel gas from the integrated fueling and charging system to the vehicle, receiving an indication of a failure of at least one of the first connection or the second connection; and
operating the integrated fueling and charging system to cease providing at least one of the electricity or the fuel gas from the integrated fueling and charging system to the vehicle.

7. The method of claim 6, wherein the indication of the failure of the at least one of the first connection or the second connection is associated with an interruption of an electrical loop between the electrical output and the electrical input forming the first connection.

8. The method of claim 6, wherein the indication of the failure of the at least one of the first connection or the second connection is received from one or more sensors configured generate sensor data corresponding to a leak of the fuel gas from the second connection.

9. An integrated fueling and charging system comprising:
a charging system configured to supply electricity to a vocational vehicle, the charging system comprising an electrical output configured to electrically couple with an electrical input of the vocational vehicle;
a fueling system configured to supply fuel gas to the vocational vehicle, the fueling system comprising a gas output configured to fluidly couple with a gas input of the vocational vehicle; and
one or more processing circuits configured to:
perform a first connection test on a first connection between the electrical output and the electrical input,
perform a second connection test on a second connection between the gas output and the gas input, and
responsive to the first connection passing the first connection test and the second connection passing the second connection test, operate the charging system and the fueling system to simultaneously provide the electricity and the fuel gas to the vocational vehicle.

10. The integrated fueling and charging system of claim 9, further comprising:
one or more sensors configured to generate sensor data corresponding to a leak of the fuel gas from the second connection;
wherein the one or more processing circuits are further configured to:
receive, from the one or more sensors, the sensor data, and
responsive to the leak of the fuel gas from the second connection exceeding a fuel gas leakage threshold, operate at least one of the fueling system to cease providing the fuel gas to the vocational vehicle or the charging system to cease providing the electricity to the vocational vehicle.

11. The integrated fueling and charging system of claim 9, wherein:
when the electrical input is electrically coupled with the electrical output, the electrical output is configured to form an electrical loop with the electrical input; and
responsive to receiving an interruption of the electrical loop, the one or more processing circuits are further configured to operate the at least one of the fueling system to cease providing the fuel gas to the vocational vehicle or the charging system to cease providing the electricity to the vocational vehicle.

12. The integrated fueling and charging system of claim 9, wherein the first connection test and the second connection test are performed sequentially.

13. The integrated fueling and charging system of claim 9, wherein, responsive to at least one of the first connection failing the first connection test or the second connection failing the second connection test, the one or more processing circuits are further configured to operate the fueling system and the charging system to sequentially provide the electricity and the fuel gas to the vocational vehicle.

14. The integrated fueling and charging system of claim 13, further comprising:
a user interface configured to receive an operator input from an operator of the integrated fueling and charging system;
wherein the one or more processing circuits are configured to operate the fueling system and the charging system to sequentially provide the electricity and the fuel gas to the vocational vehicle in response to receiving an indication of the operator input from the user interface.

15. The integrated fueling and charging system of claim 13, wherein when the electricity and the fuel gas are sequentially provided to the vocational vehicle, the fuel gas is provided to the vocational vehicle before the electricity is provided to the vocational vehicle.

16. A system comprising:
a vehicle comprising:
a fuel gas tank configured to store a fuel gas,
a gas input fluidly coupled to the fuel gas tank,
a battery configured to store electricity, and
an electrical input electrically coupled to the battery;
a fueling system comprising a gas output configured to fluidly couple with the gas input;
a charging system comprising an electrical output configured to electrically couple with the electrical input; and
one or more processing circuits configured to:
perform a first connection test on a first connection between the electrical output and the electrical input,
perform a second connection test on a second connection between the gas output and the gas input, and
responsive to the first connection passing the first connection test and the second connection passing the second connection test, operate the charging system and the fueling system to simultaneously provide the electricity and the fuel gas to the vehicle.

17. The system of claim 16, wherein the first connection test and the second connection test are performed sequentially.

18. The system of claim 16, further comprising:
one or more sensors configured to generate sensor data corresponding to a leak of the fuel gas from the second connection;
wherein the one or more processing circuits are further configured to:
receive, from the one or more sensors, the sensor data, and
responsive to the leak of the fuel gas from the second connection exceeding a fuel gas leakage threshold, operate at least one of the fueling system to cease providing the fuel gas to the vehicle or the charging system to cease providing the electricity to the vehicle.

19. The system of claim 16, wherein:
when the electrical input is electrically coupled with the electrical output, the electrical output and the electrical input form an electrical loop; and
responsive to receiving an interruption of the electrical loop, the one or more processing circuits are further configured to operate at least one of the fueling system to cease providing the fuel gas to the vehicle or the charging system to cease providing the electricity to the vehicle.

20. The system of claim 16, wherein, responsive to at least one of the first connection failing the first connection test or the second connection failing the second connection test, the one or more processing circuits are further configured to operate the fueling system and the charging system to sequentially provide the electricity and the fuel gas to the vehicle.
